(19) United States
(12) Patent Application Publication
(10) Pub. No.: US 2024/0090293 A1
(43) Pub. Date: Mar. 14, 2024

(54) DISPLAY SUBSTRATE, MANUFACTURING METHOD THEREOF AND DISPLAY DEVICE

(71) Applicants: MIANYANG BOE OPTOELECTRONICS TECHNOLOGY CO., LTD., Mianyang,Sichuan (CN); BOE TECHNOLOGY GROUP CO., LTD., Beijing (CN)

(72) Inventors: Yaohong TAN, Beijing (CN); Quanjun WANG, Beijing (CN); Feng BAI, Beijing (CN); Jenyu LEE, Beijing (CN); Wen SUN, Beijing (CN)

(21) Appl. No.: 17/918,256

(22) PCT Filed: Nov. 29, 2021
(86) PCT No.: PCT/CN2021/134166

§ 371 Date: Oct. 11, 2022

(51) Int. Cl. H10K 59/35; H10K 59/122; H10K 59/80; H10K 71/20

(52) U.S. Cl. CPC H10K 59/353; H10K 59/122; H10K 59/352; H10K 59/80518; H10K 59/878; H10K 71/20

(57) ABSTRACT

A display substrate, a manufacturing method and a display device are provided. The display substrate includes: a base substrate and a plurality of sub-pixels; a pixel definition layer arranged on the base substrate and including a plurality of pixel openings, a region where the pixel opening is located being an active light-emitting region of a corresponding sub-pixel; a plurality of post spacers arranged at a side of the pixel definition layer away from the base substrate and configured to support a mask in an evaporation process of the display substrate; and a reflection layer arranged between the post spacer and the base substrate. An orthogonal projection of each post spacer onto the base substrate at least partially overlaps an orthogonal projection of the reflection layer onto the base substrate.

### CROSS-REFERENCE TO RELATED APPLICATION

This application is the U.S. national phase of PCT Application No. PCT/CN2021/134166 filed on Nov. 29, 2021, which is incorporated herein by reference in its entirety.

### TECHNICAL FIELD

The present disclosure relates to the field of display technology, in particular to a display substrate, a manufacturing method thereof, and a display device.

### BACKGROUND

For an organic light-emitting diode display panel, its manufacture process includes forming a plurality of post spacers to support a mask, and forming a light-emitting function layer through evaporation. During the evaporation, particles occur inevitably. These particles may fall onto the light-emitting functional layer or may be adhered to the mask. When the mask is used again and in contact with a post spacer, the particles may be transferred to structures of the display panel other than the light-emitting functional layer.

### SUMMARY

An object of the present disclosure is to provide a display substrate, its manufacturing method and a display device, so as to solve the above-mentioned problems.

In order to achieve the above-mentioned object, the present disclosure provides the following technical solutions.

In one aspect, the present disclosure provides in some embodiments a display substrate, including: a base substrate and a plurality of sub-pixels; a pixel definition layer arranged on the base substrate and including a plurality of pixel openings, a region where the pixel opening is located being an active light-emitting region of a corresponding sub-pixel; a plurality of post spacers arranged at a side of the pixel definition layer away from the base substrate and configured to support a mask in an evaporation process of the display substrate; and a reflection layer arranged between the post spacer and the base substrate. An orthogonal projection of each post spacer onto the base substrate at least partially overlaps, or at least does not partially overlap, an orthogonal projection of the reflection layer onto the base substrate.

In a possible embodiment of the present disclosure, the reflection layer includes at least one protrusion protruding along a direction away from the base substrate.

In a possible embodiment of the present disclosure, the reflection layer includes one or more of a first structure where the reflection layer includes a first transparent layer, an intermediate reflection layer and a second transparent layer laminated one on another in a direction away from the base substrate, a second structure where the reflection layer includes a third transparent layer and a top reflection layer laminated one on another in the direction away from the base substrate, a third structure where the reflection layer includes a bottom reflection layer and a fourth transparent layer laminated one on another in the direction away from the base substrate, and a fourth structure where the reflection layer includes a single-layered reflection film layer.

In a possible embodiment of the present disclosure, the reflection layer is made of a non-metal material and arranged between the post spacer and the pixel definition layer.

In a possible embodiment of the present disclosure, the reflection layer includes a plurality of reflection patterns, and an orthogonal projection of each post spacer onto the base substrate is located with within an orthogonal projection of a corresponding reflection pattern onto the base substrate.

In a possible embodiment of the present disclosure, the reflection pattern is of a strip-like shape, a maximum length L of the orthogonal projection of the reflection pattern onto the base substrate in a first direction is greater than or equal to 16 μm and smaller than or equal to 20 μm, a maximum width d of the orthogonal projection of the reflection pattern onto the base substrate in a second direction is greater than or equal to 11 μm and smaller than or equal to 15 μm, the first direction is a lengthwise direction of the reflection pattern, and the second direction is a widthwise direction of the reflection pattern.

In a possible embodiment of the present disclosure, for the orthogonal projection of each reflection pattern onto the base substrate, d is 11 μm and L is 16 μm, or d is 12 μm and L is 17 μm, or d is 13 μm and L is 18 μm, or d is 14 μm and L is 19 μm, or d is 15 μm and L is 20 μm.

In a possible embodiment of the present disclosure, a maximum length of the orthogonal projection of the post spacer onto the base substrate in the first direction is smaller than or equal to 15 μm, and a maximum width of the orthogonal projection of the post spacer onto the base substrate is smaller than or equal to 10 μm.

In a possible embodiment of the present disclosure, the display substrate further includes an anode layer arranged at a same layer as the reflection layer.

In a possible embodiment of the present disclosure, the reflection pattern is made of a reflective non-metal material, or made of a same material as the anode layer.

In a possible embodiment of the present disclosure, the anode layer includes a plurality of anode patterns independent of each other, and each anode pattern is arranged independent of the reflection pattern.

In a possible embodiment of the present disclosure, the display substrate further includes an anode layer arranged at a side of each post spacer away from the base substrate, and the reflection layer is of a grid-like structure and coupled to the anode layer.

In a possible embodiment of the present disclosure, the anode layer includes a plurality of anode patterns independent of each other, and at least a part of the reflection patterns are formed integrally with an adjacent anode pattern.

In a possible embodiment of the present disclosure, the display substrate includes a plurality of sub-pixels, and the sub-pixels corresponding to the anode pattern formed integrally with the reflection patterns emit light in a same color.

In a possible embodiment of the present disclosure, the display substrate further includes: a second planarization layer, at least a part of the second planarization layer being arranged between the pixel definition layer and the base substrate; and a second source-drain metal layer arranged between the second planarization layer and the base substrate, the reflection pattern being arranged at a same layer and made of a same material as the second source-drain metal layer.

In a possible embodiment of the present disclosure, the display substrate further includes: a second planarization layer, at least a part of the second planarization layer being arranged between the pixel definition layer and the base substrate; a first planarization layer arranged between the second planarization layer and the base substrate; and a first source-drain metal layer arranged between the first planarization layer and the base substrate, the reflection pattern being arranged at a same layer and made of a same material as the first source-drain metal layer.

In another aspect, the present disclosure provides in some embodiments a display device including the above-mentioned display substrate.

In yet another aspect, the present disclosure provides in some embodiments a method for manufacturing the above-mentioned display substrate, the display substrate including a base substrate and a plurality of sub-pixels, the method including: forming a reflection layer and a pixel definition layer on the base substrate, the pixel definition layer including a plurality of openings, a region where the opening is located being an active light-emitting region of a corresponding sub-pixel; and forming a plurality of post spacers at a side of the reflection layer away from the base substrate, the plurality of post spacers being arranged at a side of the pixel definition layer away from the base substrate and configured to support a mask in an evaporation process of the display substrate. An orthogonal projection of each post spacer onto the base substrate at least partially overlaps, or at least does not partially overlap, an orthogonal projection of the reflection layer onto the base substrate.

In a possible embodiment of the present disclosure, the forming the reflection layer on the base substrate specifically includes forming the reflection layer and an anode layer of the display substrate simultaneously through a single patterning process.

In a possible embodiment of the present disclosure, the forming the reflection layer on the base substrate specifically includes forming the reflection layer and a second source-drain metal layer of the display substrate simultaneously through a single patterning process.

In a possible embodiment of the present disclosure, the forming the reflection layer on the base substrate specifically includes forming the reflection layer and a first source-drain metal layer simultaneously through a single patterning process.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure.

FIG. 1 is a partial sectional view of a display substrate in the related art;

FIG. 2 is a sectional view of a display substrate according to one embodiment of the present disclosure;

FIG. 3 is a top view of the display substrate according to one embodiment of the present disclosure;

FIG. 4 is another top view of the display substrate according to one embodiment of the present disclosure;

FIG. 5 is yet another top view of the display substrate according to one embodiment of the present disclosure;

FIG. 6 is still yet another top view of the display substrate according to one embodiment of the present disclosure;

FIG. 7 is still yet another top view of the display substrate according to one embodiment of the present disclosure;

FIG. 8 is still yet another top view of the display substrate according to one embodiment of the present disclosure;

FIG. 9 is a partial top electron micrograph of the display substrate according to one embodiment of the present disclosure;

FIG. 10 is a partial sectional electron micrograph of the display substrate according to one embodiment of the present disclosure;

FIG. 11 is still yet another top view of the display substrate according to one embodiment of the present disclosure;

FIG. 12 is still yet another top view of the display substrate according to one embodiment of the present disclosure;

FIG. 13 is another sectional view of the display substrate according to one embodiment of the present disclosure;

FIG. 14 is yet another sectional view of the display substrate according to one embodiment of the present disclosure;

FIG. 15 is still yet another sectional view of the display substrate according to one embodiment of the present disclosure;

FIG. 16 is still yet another sectional view of the display substrate according to one embodiment of the present disclosure;

FIG. 17 is still yet another sectional view of the display substrate according to one embodiment of the present disclosure;

FIG. 18 is still yet another sectional view of the display substrate according to one embodiment of the present disclosure;

FIG. 19 is still yet another sectional view of the display substrate according to one embodiment of the present disclosure;

FIG. 20 is still yet another sectional view of the display substrate according to one embodiment of the present disclosure;

FIG. 21 is still yet another sectional view of the display substrate according to one embodiment of the present disclosure;

FIG. 22 is still yet another sectional view of the display substrate according to one embodiment of the present disclosure; and

FIG. 23 is still yet another sectional view of the display substrate according to one embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments.

During the evaporation, particles occur inevitably. These particles may fall onto a light-emitting functional layer or may be adhered to a mask. When the mask is used again and in contact with a post spacer, the particles may be transferred to structures of a display panel other than the light-emitting functional layer.

A reliability risk easily occurs due to some particles having a large size in these falling particles, and Growing Dark Spots (GDS) easily occur in the display panel. In order to solve these problems, an Automatic Optical Inspection (AOI) camera is usually used to take a photograph of the display panel, so as to detect the particles on the display panel and remove the particles having a large size, thereby to ensure the display quality of the display panel.

Currently, the particles at a normal position are capable of being detected through adjusting an algorithm and a threshold of the AOI camera, but it is difficult to detect the particles on the post spacer, so there is a risk for the quality of the display panel.

Hence, during the detection of the particles, there is an urgent need to provide a scheme for detecting the particles on the post spacer, thereby to improve the quality of the display panel.

Based on the above problems, it is found that, the particles on the post spacer are not detected easily for the following reasons.

As a first reason, in order to ensure a high pixel resolution and prevent the post spacer from being scratched, the post spacer is provided with a small size. At this time, it is impossible to provide the post spacer with a smooth, flat upper surface, and thereby it is impossible for the AOI camera to effectively recognize a contrast difference. It should be appreciated that, when the post spacer has a small size, a contact area between the post spacer and the mask supported by the post spacer is small too, so it is able to prevent the post spacer from being scratched.

As a second reason, the post spacer is of an arch-like upper surface rather than a smooth, flat upper surface, so it is impossible for the AOI camera to effectively recognize the contrast difference.

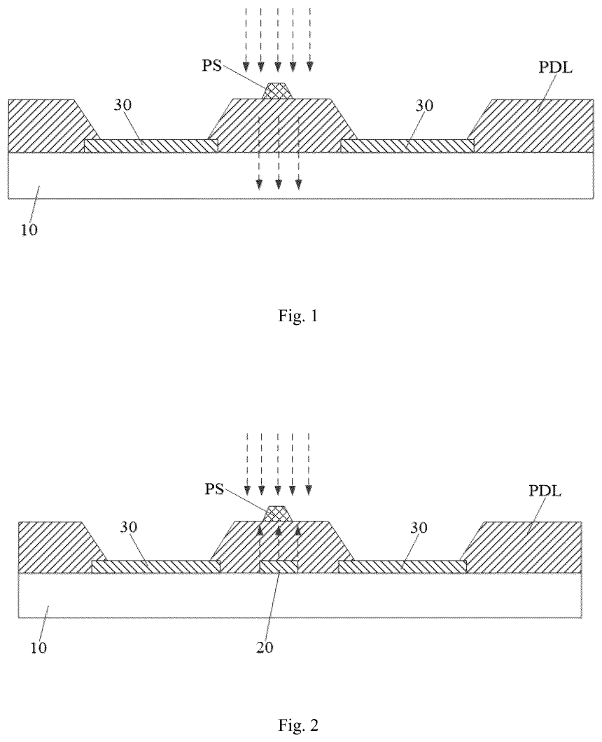

As a third reason, as shown in FIG. 1, there is no reflective film layer right below the post spacer (PS), so when the AOI camera is used to take a photogram of the post spacer, a black image is obtained. At this time, it is impossible to recognize the contrast difference between a position where the particle is located and the other position, thereby it is impossible to determine whether there is the particle.

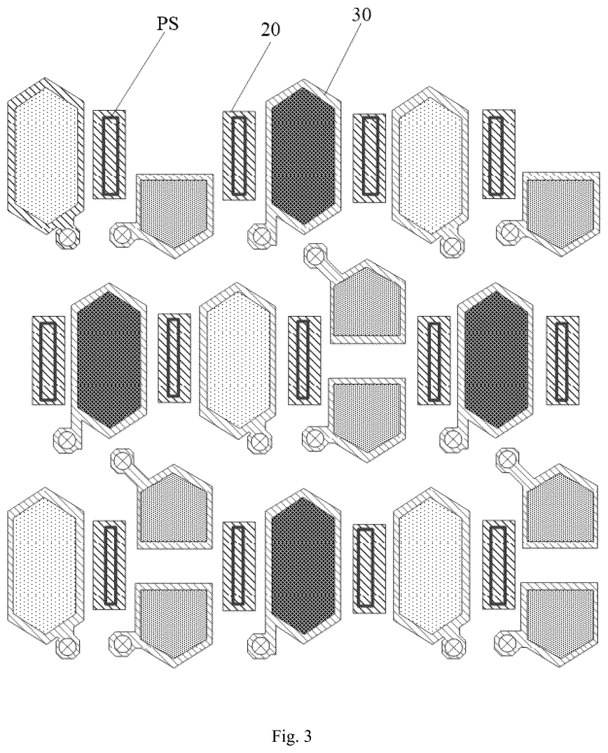

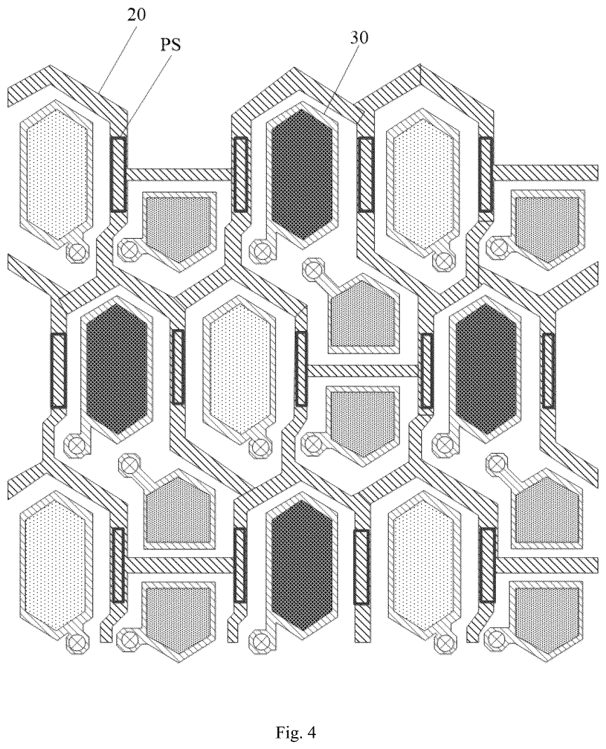

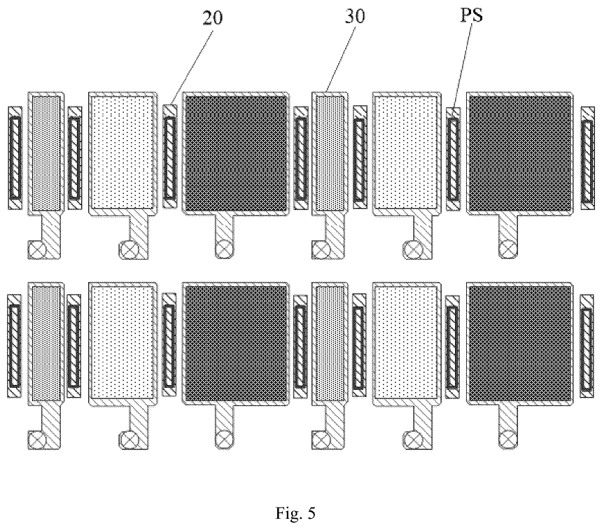

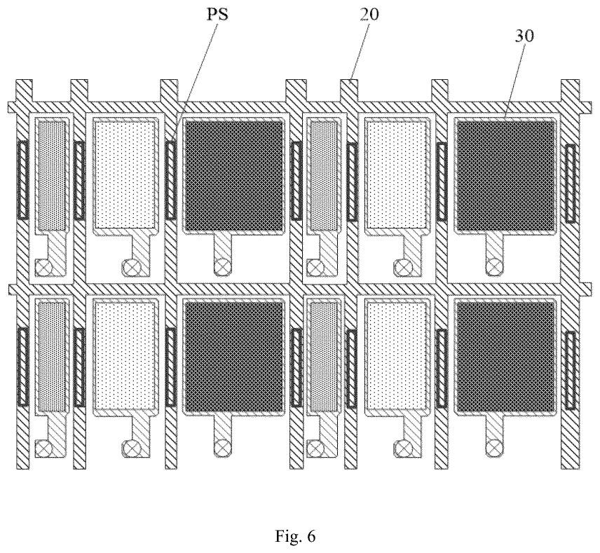

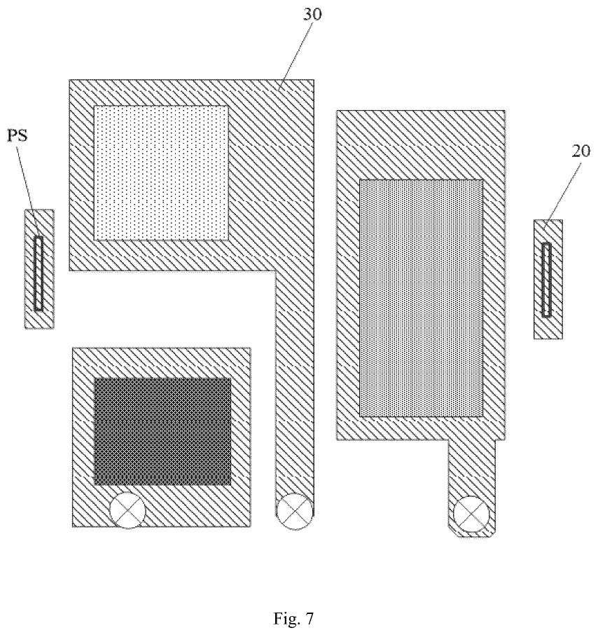

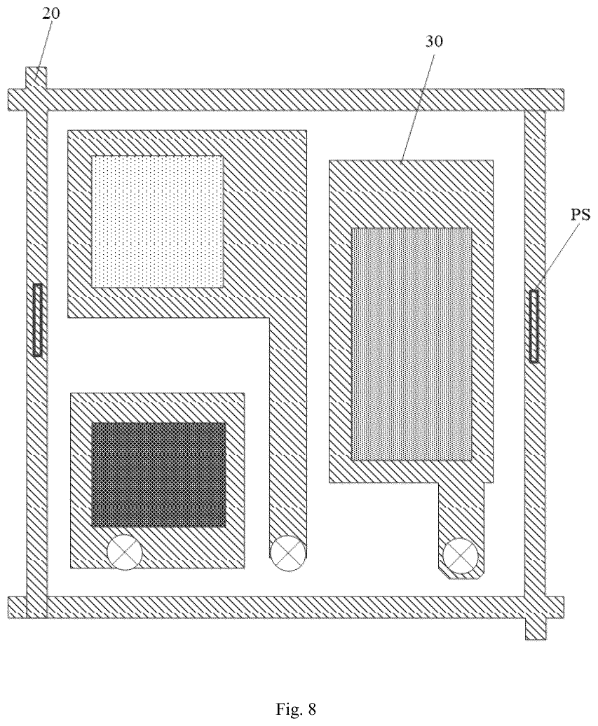

As shown in FIGS. 2 to 8, the present disclosure provides in some embodiments a display substrate, which includes a base substrate, a plurality of sub-pixels, a pixel definition layer (PDL), a plurality of post spacers (PS) and a reflection layer (including a reflection pattern 20). The pixel definition layer PDL is arranged on the base substrate and includes a plurality of pixel openings, and a region where each pixel opening is located is an active light-emitting region of a corresponding sub-pixel. The plurality of post spacers is arranged at a side of the pixel definition layer away from the base substrate, and configured to support a mask in an evaporation process of the display substrate. The reflection layer is arranged between the post spacer and the base substrate. An orthogonal projection of each post spacer onto the base substrate at least partially overlaps, or at least does not partially overlap, an orthogonal projection of the reflection layer onto the base substrate.

Illustratively, the pixel definition layer is configured to define a plurality of pixel openings corresponding to the plurality of sub-pixels respectively, and each pixel opening is an active light-emitting region of the corresponding sub-pixel.

Illustratively, the post spacer is arranged at a surface of the pixel definition layer away from the base substrate. The post spacer is formed integrally with the pixel definition layer, so the post spacer and the pixel definition layer are formed simultaneously through a single patterning process.

Illustratively, the post spacer is provided with an arch-like protrusion at the top of the post spacer. During the evaporation, the arch-like protrusion is in contact with a mask at the vertex of the post spacer, so as to support the mask. When the post spacer is provided with the arch-like protrusion at the top thereof, it is able to prevent the post spacer from being scratched by the mask and an evaporation material in a better manner.

Illustratively, the reflection layer is arranged between the pixel definition layer and the base substrate.

Illustratively, the orthogonal projection of the post spacer onto the base substrate partially overlaps the orthogonal projection of the reflection layer onto the base substrate.

Illustratively, the orthogonal projection of the post spacer onto the base substrate coincides with the orthogonal projection of the reflection layer onto the base substrate.

Illustratively, the orthogonal projection of the post spacer onto the base substrate is surrounded by the orthogonal projection of the reflection layer onto the base substrate.

Illustratively, the reflection layer is arranged between the pixel definition layer and the base substrate. Light generated by an AOI camera during the photographing reaches the post spacer from a side of the post spacer away from the base substrate, and passes through the post spacer and the pixel definition layer under the post spacer toward the reflection layer. Then, the light is reflected by the reflection layer back to the AOI camera.

Based on the above-mentioned specific structure of the display substrate, in the embodiments of the present disclosure, the reflection layer is arranged between the pixel definition layer and the base substrate, and the orthogonal projection of the post spacer onto the base substrate at least partially overlaps the orthogonal projection of the reflection layer onto the base substrate. When a foreign matter on a film layer of the display substrate is to be detected, the light generated by the AOI camera during the photographing passes through the post spacer and reflected by the reflection layer between the post spacer and the base substrate back to the AOI camera. As a result, it is able to effectively improve a photographing effect of the AOI camera on the post spacer, thereby to recognize whether there are particles on the post spacer in accordance with an image of the post spacer taken by the AOI camera in a better manner.

Hence, in the embodiments of the present disclosure, it is able to improve a detection success rate of the particles or any other foreign matters on the post spacer, e.g., approximate to 100%, while ensuring a high pixel resolution, preventing the post spacer form being scratched and maintaining an original design and an original manufacture process of the post spacer, thereby to ensure the quality of the display substrate in a better manner.

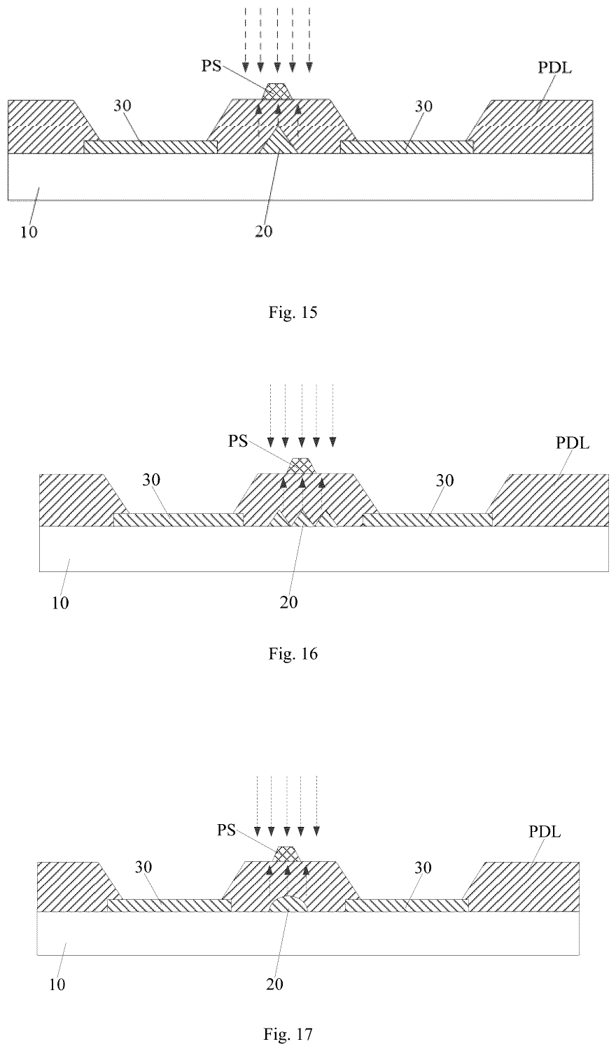

As shown in FIGS. 15 to 18, in some embodiments of the present disclosure, the reflection layer includes at least one protrusion protruding along a direction away from the base substrate.

As shown in FIGS. 15 and 17, illustratively, in a direction perpendicular to the base substrate, a cross section of the protrusion is of a triangular or semicircular shape, or a part of a circle. When the cross section of the protrusion is a part of a circle, a height of the protrusion in the direction perpendicular to the base substrate is greater than or less than a radius of the circle.

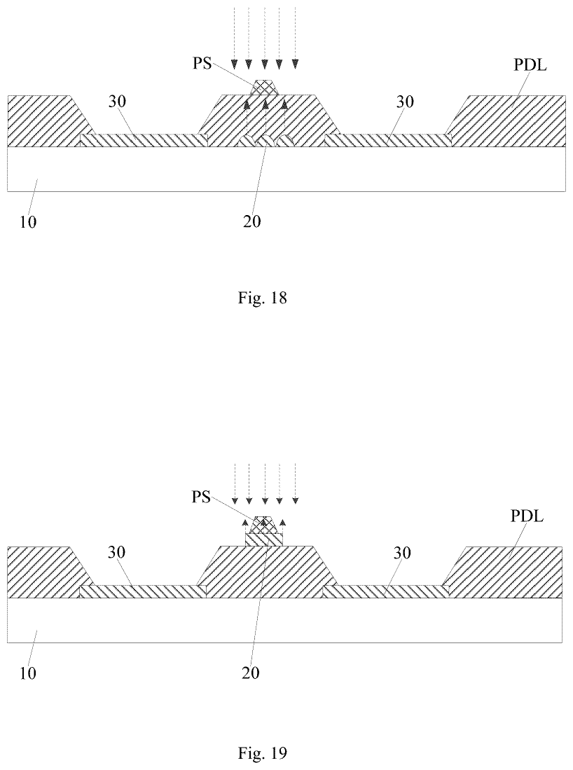

As shown in FIGS. 16 and 18, illustratively, the reflection layer includes a plurality of protrusions.

In this way, it is able to enlarge a region for reflecting the light, thereby to improve a recognition rate.

In some embodiments of the present disclosure, the reflection layer includes one or more of the following structures.

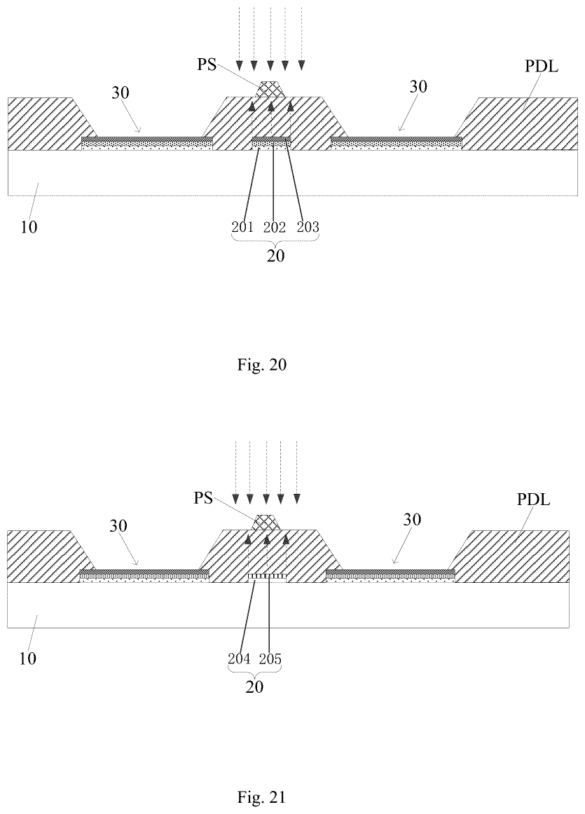

As shown in FIG. 20, in a first structure, the reflection layer 20 includes a first transparent layer 201, an intermediate reflection layer 202 and a second transparent layer 203 laminated one on another in a direction away from the base substrate. Illustratively, in the first structure, the first transparent layer 201, the intermediate reflection layer 202 and the second transparent layer 203 are each made of a same material as a corresponding film layer in an anode pattern 30. Illustratively, the anode pattern 30 includes an indium tin oxide (ITO) layer, an Ag layer and an ITO layer laminated one on another. The first transparent layer 201 and the second transparent layer 203 are made of ITO, and the intermediate reflection layer 202 is made of Ag.

As shown in FIG. 21, in a second structure, the reflection layer 20 includes a third transparent layer 204 and a top reflection layer 205 laminated one on another in the direction away from the base substrate.

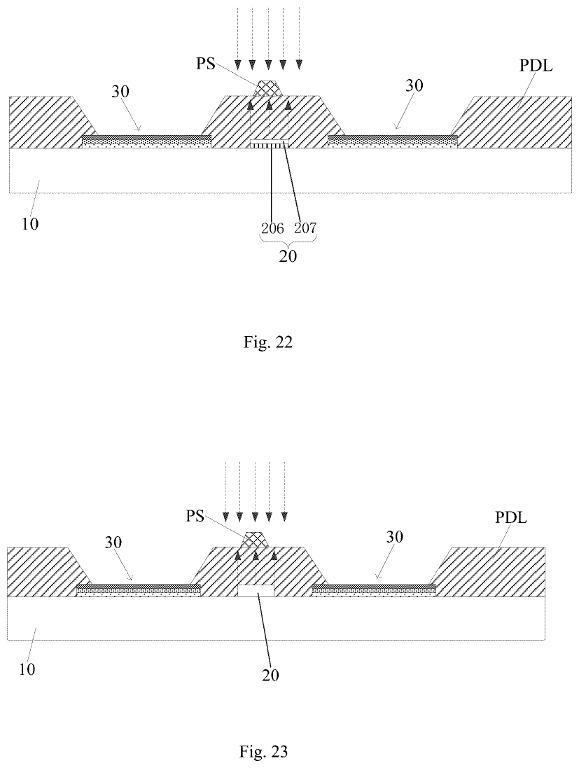

As shown in FIG. 22, in a third structure, the reflection layer 20 includes a bottom reflection layer 206 and a fourth transparent layer 207 laminated one on another in the direction away from the base substrate.

As shown in FIG. 23, in a fourth structure, the reflection layer 20 includes a single-layered reflection film layer.

As shown in FIG. 19, in some embodiments of the present disclosure, the reflection layer 20 is made of a non-metal material, and arranged between the post spacer and the pixel definition layer.

As shown in FIGS. 2 to 8, in some embodiments of the present disclosure, the orthogonal projection of the post spacer onto the base substrate is located within the orthogonal projection of the reflection layer onto the base substrate.

Illustratively, the orthogonal projection of the post spacer onto the base substrate coincides with the orthogonal projection of at least a part of the reflection layer onto the base substrate.

Based on the above, when the foreign matter on the film layer of the display substrate is to be detected, the light generated by the AOI camera during the photographing passes through the post spacer and then is reflected by the reflection layer between the post spacer and the base substrate back to the AOI camera. In this way, it is able to improve the photographing effect of the AOI camera on the post spacer, thereby to detect whether there are particles on the post spacer in accordance with the image of the post spacer taken by the AOI camera in a better manner.

As shown in FIGS. 2 to 8, in some embodiments of the present disclosure, the reflection layer includes a plurality of reflection patterns 20, and the orthogonal projection of each post spacer onto the base substrate is located within an orthogonal projection of a corresponding reflection pattern 20 onto the base substrate.

Illustratively, the plurality of reflection patterns 20 is arranged independent of each other, or formed integrally.

Illustratively, the plurality of post spacers corresponds to at least a part of the reflection patterns respectively, and the orthogonal projection of the post spacer onto the base substrate is located within the orthogonal projection of the corresponding reflection pattern 20 onto the base substrate.

Illustratively, the orthogonal projection of the post spacer onto the base substrate coincides with the orthogonal projection of the corresponding reflection pattern 20 onto the base substrate.

Illustratively, the orthogonal projection of the post spacer onto the base substrate is surrounded by the orthogonal projection of the corresponding reflection pattern 20 onto the base substrate.

Based on the above, when the foreign matter on the film layer of the display substrate is to be detected, the light generated by the AOI camera during the photographing passes through the post spacer and then is reflected by the reflection layer between the post spacer and the base substrate back to the AOI camera. In this way, it is able to improve the photographing effect of the AOI camera on the post spacer, thereby to detect whether there are particles on the post spacer in accordance with the image of the post spacer taken by the AOI camera in a better manner.

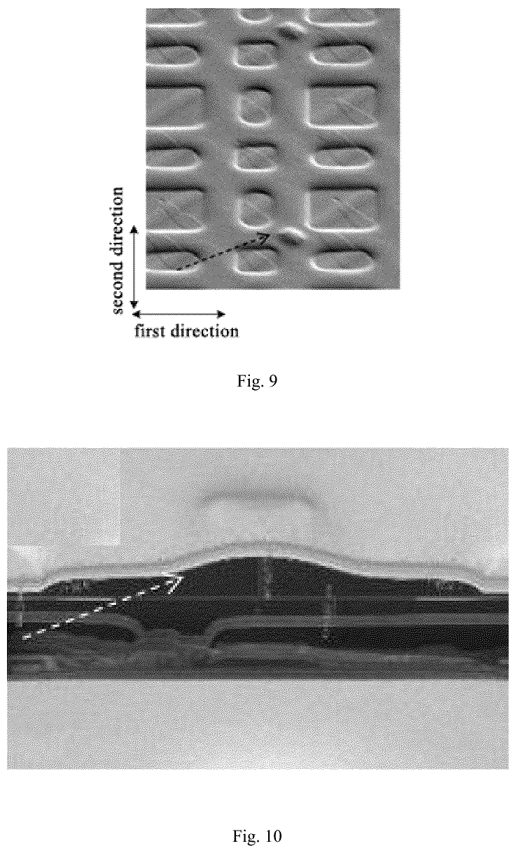

As shown in FIGS. 9 and 10, in some embodiments of the present disclosure, the reflection pattern 20 is of a strip-like shape, a maximum length L of the orthogonal projection of the reflection pattern 20 onto the base substrate in a first direction is greater than or equal to 16 μm and smaller than or equal to 20 μm, a maximum width d of the orthogonal projection of the reflection pattern onto the base substrate in a second direction is greater than or equal to 11 μm and smaller than or equal to 15 μm, the first direction is a lengthwise direction of the reflection pattern, the second direction is a widthwise direction of the reflection pattern, and the first direction intersects the second direction.

It should be appreciated that, each arrow in FIGS. 9 and 10 points toward the post spacer.

Illustratively, the first direction is perpendicular to the second direction. The first direction includes a horizontal direction, and the second direction includes a longitudinal direction.

Illustratively, the orthogonal projection of the reflection pattern 20 onto the base substrate is of a strip-like shape, the first direction is an extension direction of a long side of the reflection pattern 20, and the second direction is an extension direction of a short side of the reflection pattern 20.

Based on the above, a size of the orthogonal projection of the reflection pattern 20 onto the base substrate is greater than a size of the orthogonal projection of the small-size post spacer onto the base substrate. When the foreign matter on the film layer of the display substrate is to be detected, the light generated by the AOI camera during the photographing passes through the post spacer and then is reflected by the reflection layer between the post spacer and the base substrate back to the AOI camera. In this way, it is able to improve the photographing effect of the AOI camera on the post spacer, thereby to detect whether there are particles on the post spacer in accordance with the image of the post spacer taken by the AOI camera in a better manner.

In some embodiments of the present disclosure, for the orthogonal projection of each reflection pattern 20 onto the base substrate, d is 11 μm and L is 16 μm, or d is 12 μm and L is 17 μm, or d is 13 μm and L is 18 μm, or d is 14 μm and L is 19 μm, or d is 15 μm and L is 20 μm.

Based on the above, a size of the orthogonal projection of the reflection pattern 20 onto the base substrate is greater than a size of the orthogonal projection of the small-size post spacer onto the base substrate. When the foreign matter on the film layer of the display substrate is to be detected, the light generated by the AOI camera during the photographing passes through the post spacer and then is reflected by the reflection layer between the post spacer and the base substrate back to the AOI camera. In this way, it is able to improve the photographing effect of the AOI camera on the post spacer, thereby to detect whether there are particles on the post spacer in accordance with the image of the post spacer taken by the AOI camera in a better manner.

As shown in FIGS. 2 to 8, in some embodiments of the present disclosure, the maximum length of the orthogonal projection of the post spacer onto the base substrate in the first direction is smaller than or equal to 15 μm, and the maximum width of the orthogonal projection of the post spacer onto the base substrate in the second direction is smaller than or equal to 10 μm.

Illustratively, a height of the post spacer in a direction perpendicular to the base substrate is 1 μm.

When the post spacer has the above-mentioned size, it is able to ensure a high pixel resolution and prevent the post spacer from being scratched.

In addition, based on the above, the size of the orthogonal projection of the post spacer onto the base substrate is smaller than the size of the orthogonal projection of the reflection pattern 20 onto the base substrate. When the foreign matter on the film layer of the display substrate is to be detected, the light generated by the AOI camera during the photographing passes through the post spacer and then is reflected by the reflection layer between the post spacer and the base substrate back to the AOI camera. In this way, it is able to improve the photographing effect of the AOI camera on the post spacer, thereby to detect whether there are particles on the post spacer in accordance with the image of the post spacer taken by the AOI camera in a better manner.

As shown in FIGS. 2 to 8, in some embodiments of the present disclosure, the display substrate further includes an anode layer (including the anode pattern 30) arranged at a same layer as the reflection layer.

Illustratively, the anode layer includes a plurality of anode patterns independent of each other, a gap is provided between the adjacent anode patterns 30, and at least a part of the reflection layer is arranged in the gap.

Due to the relative large gap between the adjacent anode patterns 30, when the reflection layer is arranged at a same layer as the anode layer, it is able to prevent the occurrence of a short circuit between the reflection layer and the other conductive structure of the display substrate, and reduce the difficulty in the layout of the reflection layer.

In addition, when the reflection layer is arranged at a same layer as the anode layer, merely the pixel definition layer is arranged between the reflection layer and the post spacer. After the light passes through the pixel definition layer, it directly reaches the reflection layer, so it is able to reduce a light loss to the greatest extend, thereby to improve the photographing effect of the AOI camera on the post spacer.

In some embodiments of the present disclosure, the reflection pattern 20 is made of a reflective non-metal material.

As shown in FIGS. 2 to 8, in some embodiments of the present disclosure, the reflection patter 20 is made of a reflective metal material, or made of a same material as the anode pattern 30.

When the reflection pattern 20 is made of a reflective metal material or a same material as the anode pattern, it is able to ensure a reflection effect of the reflection layer in a better manner.

When the reflection pattern 20 is arranged at a same layer and made of a same material as the anode pattern 30, it is able to form the reflection pattern 20 and the anode pattern 30 simultaneously through a single patterning process, thereby to simplify the manufacture process and reduce the manufacture cost of the display substrate.

As shown in FIGS. 2 to 8, in some embodiments of the present disclosure, the anode layer includes a plurality of anode patterns 30 independent of each other, and each anode pattern 30 is arranged independent of the reflection pattern 20.

Illustratively, the anode pattern 30 is insulated from the reflection pattern 20.

Based on the above, when the anode pattern 30 is arranged independent of the reflection pattern 20, it is able to prevent a signal of the anode pattern 30 from being adversely affected by the reflection pattern 20.

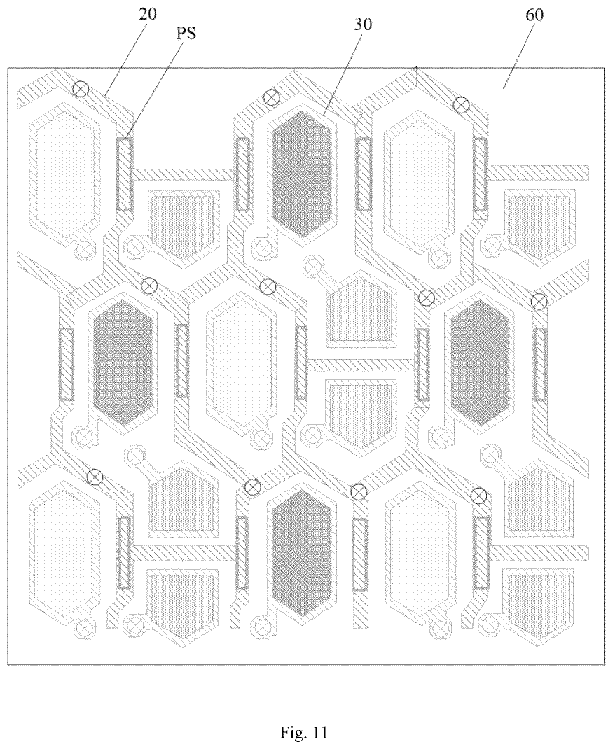

As shown in FIG. 11, in some embodiments of the present disclosure, the display substrate further includes a cathode layer 60 arranged at a side of each post spacer away from the base substrate, and the reflection layer is of a grid-like structure and coupled to the cathode layer 60.

Illustratively, the reflection layer is of the grid-like structure, at least a part of the anode patterns 30 are located in boxes of the grid-like structure, and at least a part of the anode patterns 30 are surrounded by the grid-like structure.

Based on the above, when the reflection layer is coupled to the cathode layer 60, it is able for the reflection layer to be maintained at a stable potential, thereby to ensure the operating stability of the display substrate in a better manner.

As shown in FIG. 12, in some embodiments of the present disclosure, the anode layer includes a plurality of anode patterns 30 independent of each other, and at least a part of the reflection patterns 20 and an adjacent anode pattern 30 are formed integrally.

Based on the above, it is able for the reflection pattern 20 to be maintained at a same potential as the anode pattern 30 and prevent the reflection pattern 20 from being in a floating state, thereby to ensure the operating stability of the display substrate.

In some embodiments of the present disclosure, the display substrate includes a plurality of sub-pixels, and the sub-pixels corresponding to the anode pattern formed integrally with the reflection patterns emit light in a same color.

Illustratively, the display substrate includes the plurality of sub-pixels in at least three different colors. For example, the plurality of sub-pixels includes a plurality of red sub-pixels, a plurality of green sub-pixels and a plurality of blue sub-pixels. The anode patterns 30 corresponding to the red sub-pixels have an approximately same shape, the anode patterns 30 corresponding to the green sub-pixels have an approximately same shape, and the anode patterns 30 corresponding to the blue sub-pixels have an approximately same shape.

Based on the above, the sub-pixels corresponding to the anode pattern 30 formed integrally with the reflection patterns 20 emit light in a same color, so it is able for the reflection pattern 20 to be maintained at a same potential as the anode pattern, and prevent the reflection pattern 20 from being in a floating state, thereby to improve the operating stability of the display substrate. In addition, it is able to ensure the uniformity of the anode patterns 30 corresponding to the sub-pixels in a same color in the display substrate, thereby to ensure the display quality of the display substrate in a better manner.

As shown in FIG. 14, in some embodiments of the present disclosure, the display substrate further includes: a second planarization layer 10, at least a part of the second planarization layer 10 being arranged between the pixel definition layer and the base substrate 70; and a second source-drain metal layer SD2 arranged between the second planarization layer 10 and the base substrate 70, the reflection pattern 20 being arranged at a same layer and made of a same material as the second source-drain metal layer SD2.

Illustratively, the display substrate includes a buffer layer Buf, an active layer Poly, a first gate insulation layer GI1, a first gate metal layer Gat1, a second gate insulation layer GI2, a second gate metal layer Gat2, an interlayer insulation layer ILD, a first source-drain metal layer SD1, a first passivation layer PVX1, a first planarization layer PLN1, the second source-drain metal layer SD2, a second passivation layer PVX2, the second planarization layer 10, the anode layer (including the anode patterns 30), the pixel definition layer, a light-emitting functional layer EL, the cathode layer 60 and an encapsulation structure laminated one on another in a direction away from the base substrate 70. For example, the display substrate may not include the first passivation layer PVX1 and/or the second passivation layer PVX2.

Illustratively, the sub-pixel includes a sub-pixel driving circuit. The sub-pixel driving circuit includes a plurality of transistors and a storage capacitor, and the sub-pixel driving circuit is configured to provide a driving signal for a corresponding anode pattern 30.

Illustratively, the sub-pixel driving circuit is formed through the active layer to the first source-drain metal layer. The first source-drain metal layer and the second source-drain metal layer are used to form some signal lines and conductive connection members of the display substrate.

When the reflection pattern 20 is arranged at a same layer and made of a same material as the second source-drain metal layer, it is able to form the reflection layer and the second source-drain metal layer of the display substrate simultaneously through a single patterning process without any additional patterning process for forming the reflection layer, thereby to simplify the manufacture process and reduce the manufacture cost of the display substrate.

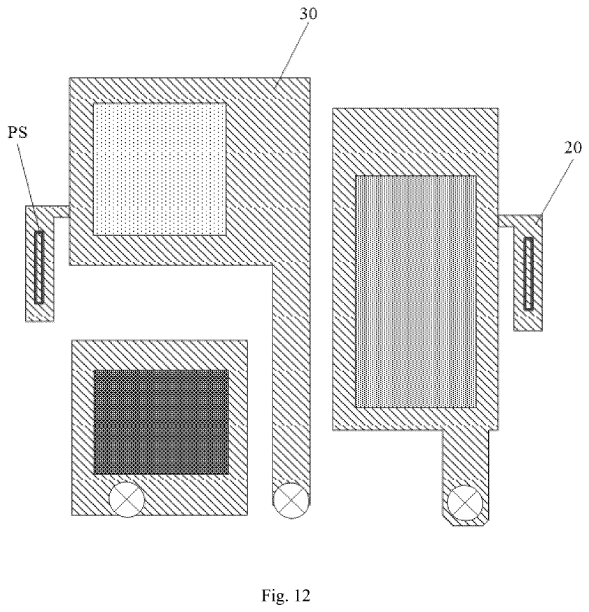

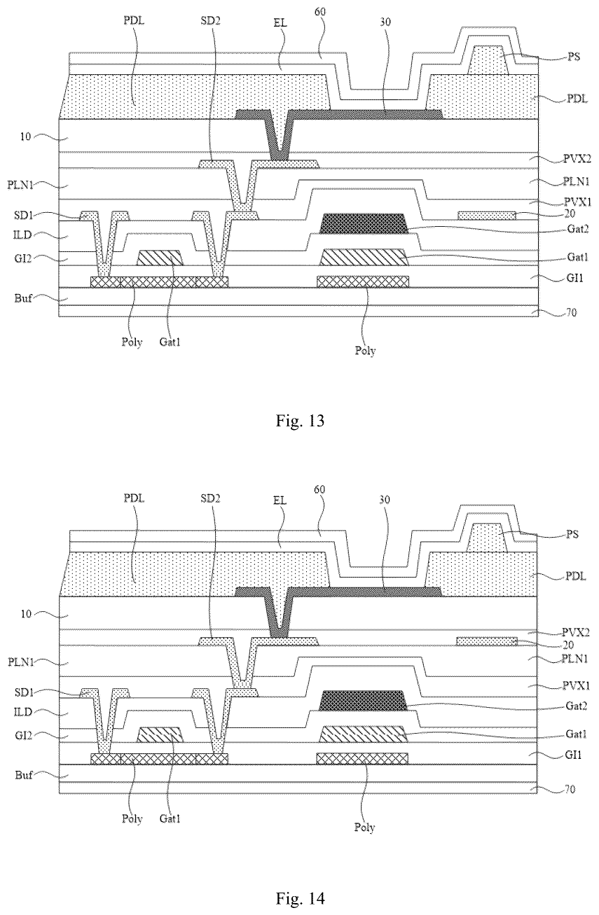

As shown in FIG. 13, in some embodiments of the present disclosure, the display substrate further includes: a second planarization layer 10, at least a part of the second planarization layer 10 being arranged between the pixel definition layer and the base substrate 70; a first planarization layer PLN1 arranged between the second planarization layer 10 and the base substrate 70; and a first source-drain metal layer SD1 arranged between the first planarization layer PLN1 and the base substrate 70, the reflection pattern 20 being arranged at a same layer and made of a same material as the first source-drain metal layer SD1.

When the reflection pattern 20 is arranged at a same layer and made of a same material as the first source-drain metal layer SD1, it is able to form the reflection layer and the first source-drain metal layer SD1 of the display substrate simultaneously through a single patterning process without any additional patterning process for forming the reflection layer, thereby to simplify the manufacture process and reduce the manufacture cost of the display substrate.

In some embodiments of the present disclosure, the display substrate further includes: an anode layer arranged between the pixel definition layer PDL1 and the base substrate; a pixel circuit array layer, at least a part of the pixel circuit array layer being arranged between the anode layer and the base substrate; a light-emitting functional layer, at least a part of the light-emitting functional layer being arranged at a side of each post spacer away from the base substrate; a cathode layer arranged at a side of the light-emitting functional layer away from the base substrate; and an encapsulation layer arranged at a side of the cathode layer away from the base substrate.

Illustratively, the pixel circuit array layer includes a plurality of sub-pixel driving circuits arranged in an array form.

Illustratively, the light-emitting functional layer includes an electron injection layer, an electron transport layer, an organic light-emitting material layer, a hole transport layer and a hole injection layer laminated one on another.

Illustratively, the encapsulation layer includes a first inorganic encapsulation layer, an organic encapsulation layer and a second inorganic encapsulation layer laminated one on another.

The present disclosure further provides in some embodiments a display device including the above-mentioned display substrate.

It should be appreciated that, the display device may be any product or member having a display function, e.g., television, display, digital photo frame, mobile phone or tablet computer. The display device further includes a flexible circuit board, a printed circuit board and a back plate.

According to the display substrate in the embodiments of the present disclosure, the reflection layer is arranged between the pixel definition layer and the base substrate, and the orthogonal projection of the post spacer onto the base substrate at least partially overlaps the orthogonal projection of the reflection layer onto the base substrate. When a foreign matter on a film layer of the display substrate is to be detected, the light generated by the AOI camera during the photographing passes through the post spacer and reflected by the reflection layer between the post spacer and the base substrate back to the AOI camera. As a result, it is able to effectively improve a photographing effect of the AOI camera on the post spacer, thereby to recognize whether there are particles on the post spacer in accordance with an image of the post spacer taken by the AOI camera in a better manner. Hence, in the embodiments of the present disclosure, it is able to improve a detection success rate of the particles or any other foreign matters on the post spacer, e.g., approximate to 100%, while ensuring a high pixel resolution, preventing the post spacer form being scratched and maintaining an original design and an original manufacture process of the post spacer, thereby to ensure the quality of the display substrate in a better manner.

Hence, when the display device includes the above-mentioned display substrate, it also has the above-mentioned beneficial effects, which will not be particularly defined herein.

The present disclosure further provides in some embodiments a method of manufacturing the above-mentioned display substrate. The display substrate includes a base substrate and a plurality of sub-pixels. The method includes: forming a reflection layer and a pixel definition layer on the base substrate, the pixel definition layer including a plurality of openings, a region where the opening is located being an active light-emitting region of a corresponding sub-pixel; and forming a plurality of post spacers at a side of the reflection layer away from the base substrate, the plurality of post spacers being arranged at a side of the pixel definition layer away from the base substrate and configured to support a mask in an evaporation process of the display substrate. An orthogonal projection of each post spacer onto the base substrate at least partially overlaps, or at least does not partially overlap, an orthogonal projection of the reflection layer onto the base substrate.

According to the display substrate manufactured through the method in the embodiments of the present disclosure, the reflection layer is arranged between the pixel definition layer and the base substrate, and the orthogonal projection of the post spacer onto the base substrate at least partially overlaps the orthogonal projection of the reflection layer onto the base substrate. When a foreign matter on a film layer of the display substrate is to be detected, the light generated by the AOI camera during the photographing passes through the post spacer and reflected by the reflection layer between the post spacer and the base substrate back to the AOI camera. As a result, it is able to effectively improve a photographing effect of the AOI camera on the post spacer, thereby to recognize whether there are particles on the post spacer in accordance with an image of the post spacer taken by the AOI camera in a better manner. Hence, in the embodiments of the present disclosure, it is able to improve a detection success rate of the particles or any other foreign matters on the post spacer, e.g., approximate to 100%, while ensuring a high pixel resolution, preventing the post spacer form being scratched and maintaining an original design and an original manufacture process of the post spacer, thereby to ensure the quality of the display substrate in a better manner.

In some embodiments of the present disclosure, the forming the reflection layer on the base substrate specifically includes forming the reflection layer and an anode layer of the display substrate simultaneously through a single patterning process.

The reflection layer and the anode layer of the display substrate are simultaneously formed through a single patterning process without any additional patterning process for forming the reflection layer, so as to simplify the manufacture process and reduce the manufacture cost of the display substrate.

In some embodiments of the present disclosure, the forming the reflection layer on the base substrate specifically includes forming the reflection layer and a second source-drain metal layer of the display substrate simultaneously through a single patterning process.

The reflection layer and the second source-drain metal layer of the display substrate are simultaneously formed through a single patterning process without any additional patterning process for forming the reflection layer, so as to simplify the manufacture process and reduce the manufacture cost of the display substrate.

In some embodiments of the present disclosure, the forming the reflection layer on the base substrate specifically includes forming the reflection layer and a first source-drain metal layer simultaneously through a single patterning process.

The reflection layer and the first source-drain metal layer of the display substrate are simultaneously formed through a single patterning process without any additional patterning process for forming the reflection layer, so as to simplify the manufacture process and reduce the manufacture cost of the display substrate.

It should be appreciated that, the expression “at a same layer” refers to that the film layers are arranged on a same structural layer. Alternatively, for example, the film layers on a same layer may be layer structures formed through forming thin layers for forming specific patterns through a single-film-forming process and then patterning the film layers with a same mask through a single patterning process. Depending on different specific patterns, a single patterning process may include multiple exposing, development or etching processes, and the specific patterns in the layer structure may be continuous or discontinuous. These specific patterns may also be arranged at different levels or have different thicknesses.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A display substrate, comprising:
a base substrate and a plurality of sub-pixels;
a pixel definition layer arranged on the base substrate and comprising a plurality of pixel openings, a region where the pixel opening is located being an active light-emitting region of a corresponding sub-pixel;
a plurality of post spacers arranged at a side of the pixel definition layer away from the base substrate and configured to support a mask in an evaporation process of the display substrate; and
a reflection layer arranged between the post spacer and the base substrate,
wherein an orthogonal projection of each post spacer onto the base substrate at least partially overlaps, or at least does not partially overlap, an orthogonal projection of the reflection layer onto the base substrate.

2. The display substrate according to claim 1, wherein the reflection layer comprises at least one protrusion protruding along a direction away from the base substrate.

3. The display substrate according to claim 1, wherein the reflection layer comprises one or more of structures:
a first structure where the reflection layer comprises a first transparent layer, an intermediate reflection layer and a second transparent layer laminated one on another in a direction away from the base substrate,
a second structure where the reflection layer comprises a third transparent layer and a top reflection layer laminated one on another in the direction away from the base substrate,
a third structure where the reflection layer comprises a bottom reflection layer and a fourth transparent layer laminated one on another in the direction away from the base substrate, and
a fourth structure where the reflection layer comprises a single-layered reflection film layer.

4. The display substrate according to claim 1, wherein the reflection layer is made of a non-metal material and arranged between the post spacer and the pixel definition layer.

5. The display substrate according to claim 1, wherein the reflection layer comprises a plurality of reflection patterns, and an orthogonal projection of each post spacer onto the base substrate is located with within an orthogonal projection of a corresponding reflection pattern onto the base substrate.

6. The display substrate according to claim 5, wherein the reflection pattern is of a strip-like shape, a maximum length L of the orthogonal projection of the reflection pattern onto the base substrate in a first direction is greater than or equal to 16 μm and smaller than or equal to 20 μm, a maximum width d of the orthogonal projection of the reflection pattern onto the base substrate in a second direction is greater than or equal to 11 μm and smaller than or equal to 15 μm, the first direction is a lengthwise direction of the reflection pattern, and the second direction is a widthwise direction of the reflection pattern.

7. The display substrate according to claim 6, wherein the orthogonal projection of each reflection pattern onto the base substrate meets one or more of the following sizes:
d is 11 μm and L is 16 μm, or
d is 12 μm and L is 17 μm, or
d is 13 μm and L is 18 μm, or
d is 14 μm and L is 19 μm, or
d is 15 μm and L is 20 μm.

8. The display substrate according to claim 6, wherein a maximum length of the orthogonal projection of the post spacer onto the base substrate in the first direction is smaller than or equal to 15 μm, and a maximum width of the orthogonal projection of the post spacer onto the base substrate in the second direction is smaller than or equal to 10 μm.

9. The display substrate according to claim 5, further comprising an anode layer arranged at a same layer as the reflection layer.

10. The display substrate according to claim 9, wherein the reflection pattern is made of a reflective non-metal material, or made of a same material as the anode layer.

11. The display substrate according to claim 9, wherein the anode layer comprises a plurality of anode patterns independent of each other, and each anode pattern is arranged independent of the reflection pattern.

12. The display substrate according to claim 9, further comprising an anode layer arranged at a side of the plurality of post spacers away from the base substrate, wherein the reflection layer is of a grid-like structure and coupled to the anode layer.

13. The display substrate according to claim 9, wherein the anode layer comprises a plurality of anode patterns independent of each other, and at least a part of the reflection patterns are formed integrally with an adjacent anode pattern, wherein the display substrate comprises a plurality of sub-pixels, and the sub-pixels corresponding to the anode pattern formed integrally with the reflection patterns emit light in a same color.

14. (canceled)

15. The display substrate according to claim 5, further comprising:
a second planarization layer, at least a part of the second planarization layer being arranged between the pixel definition layer and the base substrate; and
a second source-drain metal layer arranged between the second planarization layer and the base substrate, the reflection pattern being arranged at a same layer and made of a same material as the second source-drain metal layer.

16. The display substrate according to claim 5, further comprising:
a second planarization layer, at least a part of the second planarization layer being arranged between the pixel definition layer and the base substrate;
a first planarization layer arranged between the second planarization layer and the base substrate; and
a first source-drain metal layer arranged between the first planarization layer and the base substrate, the reflection pattern being arranged at a same layer and made of a same material as the first source-drain metal layer.

17. A display device, comprising the display substrate according to claim 1.

18. A method for manufacturing the display substrate according to claim 1, the display substrate comprising a base substrate and a plurality of sub-pixels, the method comprising:
forming a reflection layer and a pixel definition layer on the base substrate, the pixel definition layer comprising a plurality of openings, a region where the opening is located being an active light-emitting region of a corresponding sub-pixel; and
forming a plurality of post spacers at a side of the reflection layer away from the base substrate, the plurality of post spacers being arranged at a side of the pixel definition layer away from the base substrate and configured to support a mask in an evaporation process of the display substrate,
wherein an orthogonal projection of each post spacer onto the base substrate at least partially overlaps, or at least does not partially overlap, an orthogonal projection of the reflection layer onto the base substrate.

19. The method according to claim 18, wherein the forming the reflection layer on the base substrate specifically comprises forming the reflection layer and an anode layer of the display substrate simultaneously through a single patterning process.

20. The method according to claim 18, wherein the forming the reflection layer on the base substrate specifically comprises forming the reflection layer and a second source-drain metal layer of the display substrate simultaneously through a single patterning process.

21. The method according to claim 18, wherein the forming the reflection layer on the base substrate specifically comprises forming the reflection layer and a first source-drain metal layer of the display substrate simultaneously through a single patterning process.
